(19) United States
(12) Patent Application Publication
(10) Pub. No.: US 2015/0236175 A1
(43) Pub. Date: Aug. 20, 2015

(54) AMORPHOUS SILICON PASSIVATED CONTACTS FOR BACK CONTACT BACK JUNCTION SOLAR CELLS

(71) Applicant: Solexel, Inc., Milpitas, CA (US)

(72) Inventors: Pawan Kapur, Burlingame, CA (US); Heather Deshazer, Palo Alto, CA (US); Mohammed Islam, Mountain House, CA (US); Mehrdad M. Moslehi, Los Altos, CA (US)

(21) Appl. No.: 14/582,090

(22) Filed: Dec. 23, 2014

Related U.S. Application Data
(63) Continuation-in-part of application No. 14/576,161, filed on Dec. 18, 2014.
Application No. 14/576,161 is a continuation-in-part of application No. 14/558,707, filed on Dec. 2, 2014.
(60) Provisional application No. 61/920,209, filed on Dec. 23, 2013.
(60) Provisional application No. 61/917,919, filed on Dec. 18, 2013.
(60) Provisional application No. 61/910,936, filed on Dec. 2, 2013.

(51) Int. Cl. H01L 31/0224; H01L 31/02; H01L 31/0216

(52) U.S. Cl. CPC H01L 31/022441; H01L 31/02167; H01L 31/02008

(57) ABSTRACT

Passivated contact structures and fabrication methods for back contact back junction solar cells are provided. According to one example embodiment, a back contact back junction photovoltaic solar cell is described that has a semiconductor light absorbing layer having a front side and a backside having base regions and emitter regions. An amorphous silicon passivating layer is positioned on the base regions. A first level base and emitter metallization contacts the emitter regions and the amorphous silicon passivating layer on the base regions. An electrically insulating backplane is positioned on the first level base and emitter metallization. A second level metallization contacts the first level base and emitter metallization through conductive vias in the electrically insulating backplane.

### CROSS-REFERENCE TO RELATED APPLICATIONS

This application claims the benefit of U.S. provisional patent application 61/920,209 filed on Dec. 23, 2013, which is hereby incorporated by reference in its entirety.

This application is also a continuation-in-part of U.S. application Ser. No. 14/576,161 filed Dec. 18, 2014 which claims the benefit of U.S. provisional patent application 61/917,919 filed on Dec. 18, 2013 and is a continuation-in-part of U.S. application Ser. No. 14/558,707 filed Dec. 2, 2014 which claims the benefit of U.S. provisional patent application 61/910,936 filed on Dec. 2, 2013, all of which are hereby incorporated by reference in their entirety.

### FIELD OF THE INVENTION

The present disclosure relates in general to the fields of photovoltaic (PV) solar cells, and more particularly to passivated contacts for solar cells.

### BACKGROUND

As photovoltaic solar cell technology is adopted as an energy generation solution on an increasingly widespread scale, fabrication and efficiency improvements relating to solar cell efficiency, metallization, material consumption, and fabrication are required. Manufacturing cost and conversion efficiency factors are driving solar cell absorbers ever thinner in thickness and larger in area, thus, increasing the mechanical fragility, efficiency, and complicating processing and handling of these thin absorber based solar cells—fragility effects increased particularly with respect to crystalline silicon absorbers.

Generally, solar cell contact structure includes conductive metallization on base and emitter diffusion areas—for example aluminum metallization connecting silicon in base and emitter contact areas through relatively heavy phosphorous and boron areas, respectively.

Often, relatively heavy dopings may be needed to make a low contact resistance (less than 1 mohm-cm2 resistivity) to silicon. The Fermi level of a metal directly in contact with silicon may be pinned in the middle of the bandgap of silicon, somewhat independent of the vacuum work function of the metal because of a very high density of surface states. This may present a large barrier for the carriers to pass through contributing to a high contact resistance. To counter this, and to get good contact resistance, heavy dopings may be employed. This allows carriers to tunnel through despite of large barriers, which reduced contact resistance. In addition to helping reduce the contact resistance, heavy doping under the contact may also rejects the type of carrier which does not contribute to photocurrent (rejects holes in the base contact area and electrons in the emitter contact area). However, this heavy doping may come at a cost, for example a dramatically increased auger recombination which contributes to a loss in carriers and increased recombination, which, in turn, decreases Jsc as well as Voc. Additionally, because the rejection interface is not abrupt, the rejection ratio is not perfect.

FIG. 1 is a cross-sectional diagram of a thin crystalline silicon solar cell. FIG. 1 shows the cross section of a thin backplane supported back contact back junction solar cell with dual level metallization having a first level metal M1 and second level metal M2. The features of this cell are described in detail in U.S. Pat. Pub. 2013/0228221 published on Sep. 5, 2013 and which is hereby incorporated by reference in its entirety. The cell of FIG. 1 does not have passivated base or emitter contacts and M1 is directly in contact with heavy n and p diffusions. The cell of FIG. 1 has a backplane which allows a thin cell to be supported with high yield through the line. It may be noted that M1 (e.g., aluminum) connects with silicon in both the base and emitter contact area through relatively heavy phosphorous and boron doping areas, respectively.

### BRIEF SUMMARY OF THE INVENTION

Therefore, a need has arisen for contacts that improve back contact back junction solar cell fabrication processes and provide increased solar cell performance. In accordance with the disclosed subject matter, passivated contacts are provided which substantially eliminates or reduces disadvantages and deficiencies associated with previously developed contacts for back contact back junction solar cells.

Amorphous silicon passivated contact structures and fabrication methods for back contact back junction solar cells are provided. According to one example embodiment, a back contact back junction photovoltaic solar cell is described that has a semiconductor light absorbing layer having a front side and a backside having base regions and emitter regions. An amorphous silicon passivating layer is positioned on the base regions. A first level base and emitter metallization contacts the emitter regions and the amorphous silicon passivating layer on the base regions. An electrically insulating backplane is positioned on the first level base and emitter metallization. A second level metallization contacts the first level base and emitter metallization through conductive vias in the electrically insulating backplane.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGURES and detailed description.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a cross-sectional diagram of a thin crystalline silicon solar cell;

FIG. 2 is a band diagram for an n-type contact under flat band conditions;

FIG. 3 is a band diagram for a p-type contact under flat band conditions;

FIG. 4 is a schematic diagram of passivated contact embodiments;

FIG. 5 is a representative non-passivated contact process flow for the fabrication of a thin backplane supported back contacted back junction cell;

FIG. 6 is a cross-sectional diagram of an exemplary passivated contact thin backplane supported back contact back junction solar cell;

FIG. 7 is a cross-sectional diagram of a passivated base contact and non-passivated non-selective emitter solar cell;

FIG. 8 is a cross-sectional diagram of a passivated base contact and non-passivated selective emitter solar cell;

FIG. 9 is a cross-sectional diagram of a backplane supported thin back contact back junction solar cell (e.g., interdigitated back contact) having double amorphous silicon (a-Si) passivated contacts;

FIG. 10 is a front-end process flow which shows the front-end method to make an amorphous silicon passivated interdigitated back contact solar cell (ASP-IBC);

FIG. 11 is a front-end method for manufacturing a single passivated (n− base) with an n− base amorphous silicon passivated interdigitated back contact solar cell (ASP-IBC);

FIGS. 12A through 12C are front end solar cell fabrication flows where both base and emitter contacts are passivated with a-Si; and

FIGS. 13A through 13M are cross-sectional diagrams showing a solar cell throughout the fabrication steps of FIG. 12B.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings. The dimensions of drawings provided are not shown to scale.

And although the present disclosure is described with reference to specific embodiments and components, such as a back contact back junction (BCBJ) solar cell, one skilled in the art could apply the principles discussed herein to other solar cell structures solar cell semiconductor materials (such as GaAs, compound III-V materials), fabrication processes (such as various deposition, contact opening, and diffusion methods and materials), as well as absorber/passivation/metallization materials and formation, technical areas, and/or embodiments without undue experimentation.

Particularly, the backplane based back contact back junction process flows provided may be extended to CZ monocrystalline or multicrystalline starting material as well as epitaxial grown semiconductor (e.g., silicon) thin backplane supported BCBJ solar cells. Further, the contact types described here are generically also applicable for regular (non-backplane based) interdigitated back contact (IBC) solar cells using either CZ monocrystalline or multicrystalline starting material as well as epitaxially grown thin semiconductor (e.g., silicon).

The thin crystalline silicon based back contact back junction (BCBJ) solar cells with passivated contacts described provide passivation schemes involves using either insulators, wide bandgap (and semi-insulating) semiconductors, or a combination of the two. The passivation solutions described may provide the following two key advantages: first, the passivated contacts reduce the recombination under the contacts, and thus help increase Voc; second, if passivation is performed in an efficient manner it may significantly reduce the number of process steps and reduce costs for certain solar cells and fabrication processing.

The passivated contacts for thin BCBJ solar cells provided significantly improve surface recombination velocity under cell metallization without compromising contact resistance. Innovated aspects described include and may apply to:
The structure and integration of the passivated contacts with a thin (for example having a thickness between 10 um to 100 um) BCBJ backplane supported solar cell.
Various, different, and specific embodiments of the passivations and their combination with the overlying metal, which are used to achieve the desired high efficiency solar cell performance. For example, passivation may be wide bandgap semiconductors, a thin insulator, or a combination of both from materials such as Al2O3, HfO2, TiOx, NiOx, and ZnOx. For example, an advantageous deposition scheme being atomic layer deposition (ALD). The metal, for example, may be Aluminum (Al), Titanium (Ti), and Nickel (Ni) combined with suitable types of passivations for device physics which yield the desired results.
Particular methods related to manufacturing passivated contacts based BCBJ solar cells (with the aforementioned material set), specifically, passivated contacts based thin BCBJ solar cell which have a backplane for handling. These methods often have the added benefit of process step reduction.

Generally, passivated contact for base and emitter provided satisfy the following key conditions.
Provide very low contact resistance to the type of carriers which contributes to photocurrent (Electron for n-type base and hole for p-type emitter). Note, base and emitter are described herein in the context of n-type silicon solar cells, for a p-type solar cells the base and emitter polarities will be reversed.
Provide an excellent passivation, with, in some instances, surface recombination velocity (SRV) to be 10cm/s-100cm/s.
Provide abrupt and excellent rejection for the type of carrier which does not contribute to photocurrent (i.e., holes for base and electrons for emitter).

Additionally, the passivated contact is proposed on either heavier doped (greater than 1e17 cm-3) or lighter doped (less than 1e17 cm-3) silicon for both base and/or emitter. In some instances, and as will be evident, the lighter doped substrate contact may reduce the process steps; however, a heavier doping may be desirable to achieve the contact resistance target. Three classes of dielectric materials are proposed. Each class, distinguished by their bandgap, has several specific possibilities and in general will work with specific metals.

Dielectric Passivated contacts. The first class of passivated contacts consists of an insulator which is known to provide high quality passivation on silicon (referred to herein as passivated contact Type I or dielectric passivated contacts). A principle guideline behind Type I is depositing a very thin (e.g., 0.5 to 4 nm and in some instances more particularly 1 to 2 nm), controlled, known high quality passivating insulator layer between the silicon and the metal. Despite being ultrathin the layer is thick enough to unpin the Fermi level of the metal and take the metal from being clamped roughly at the midgap of silicon bandgap toward its natural vacuum work function level. Thus, with the right choice of vacuum work function of the metal the barrier height for tunneling of the carrier may be substantially reduced-enabling a low contact resistance. Note, the insulator should be kept thin enough such that the insulator itself does not become an obstruction and resistance to the tunneling. The thickness of the insulator should be optimized for minimum contact resistance. In addition, most insulators also exhibit better passivation quality with a larger thickness within very low thickness value ranges. For instance, it is well know that dielectrics such as ALD deposited Al2O3 SRV increases as thickness starts to drop below 2 nm. Thus, an optimal choice of the insulator thickness should consider both contact resistance optimization as well as passivation quality requirement.

Examples of insulators which provide high quality passivation on silicon are material such as Al2O3, HfOx, ZnOx, and SiO2. These examples should not be taken in the limiting sense, but are provided as guiding material selections and alternative materials which may form high quality passivation on silicon and have insulating properties may also be used. An advantageous method of deposition of these dielectrics is atomic layer deposition (ALD) as it may allow for angstrom level precise control over deposition thickness (such as may be required for tunneling current control), and high volume, solar grade, inexpensive, manufacturing tools currently exist for this process. Various surface preparations for improving passivation quality may also be used, for example an HF last process.

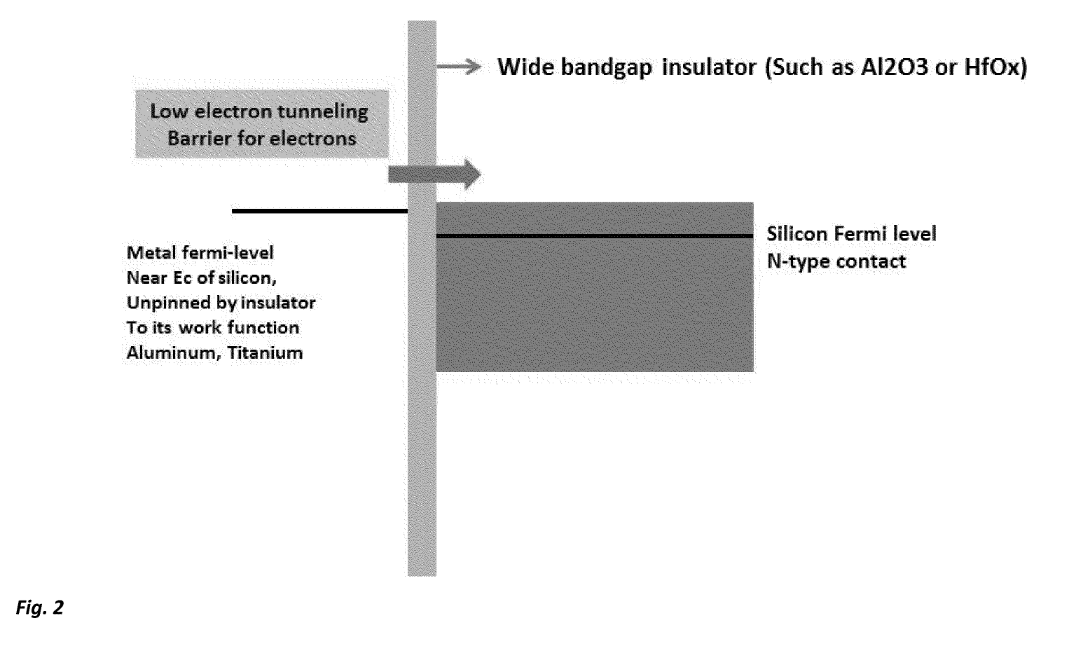

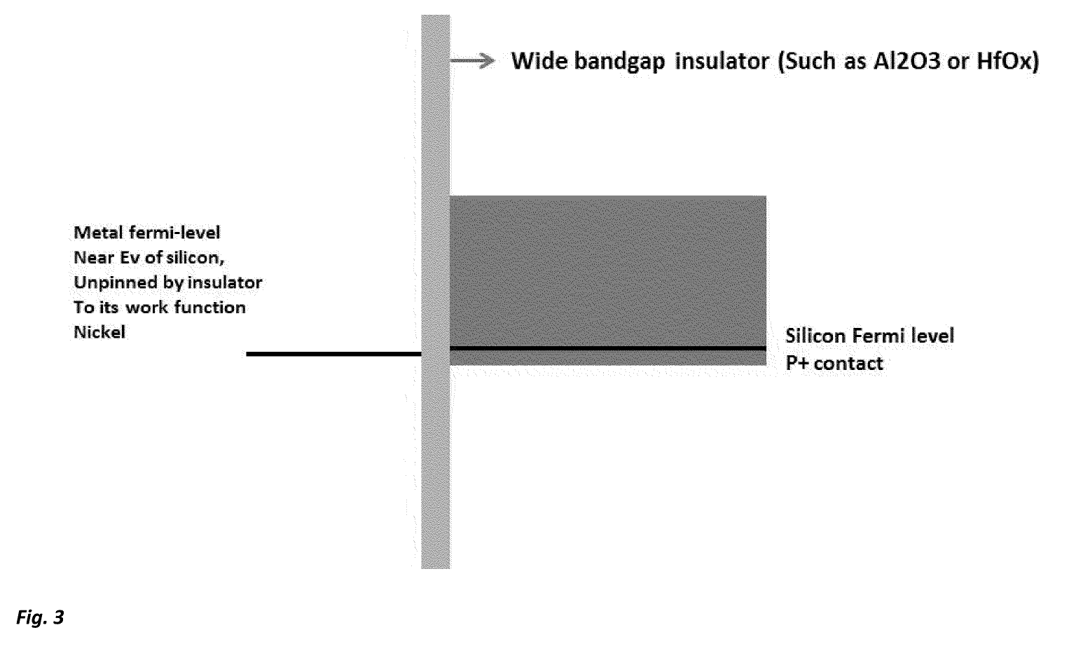

In the case of an n-type contact where the contact must provide low resistance to the electrons, the metal should be chosen to have a vacuum work function close to the conduction band of silicon. Several examples of these metals include aluminum (work function of ˜4.1 eV), titanium (work function of ˜4.3 eV), and sputtered indium tin oxide (˜4.25 eV). For the case of a p-type contact, the vacuum work function of the metal should be closer to the valence band of silicon to provide free transport of holes. Here materials such as nickel and platinum may be advantageous and metals with work functions close to the valence band of silicon may also be chosen. FIG. 2 shows the band diagram for an n-type contact under flat band condition where electrons are easy to tunnel. Specifically, FIG. 2 is a diagram showing flat band condition, band diagram with a Type I passivated contact to n-type area. FIG. 3 shows this for a p-type contact under flat band conditions. Specifically, FIG. 3 is a diagram showing flat band condition, band diagram with a Type I passivated contact to p-type area.

Wide bandgap semiconductor based passivated contacts. In this type of passivated contacts (referred to herein as passivated contact Type II or wide bandgap semiconductor based passivated contact), a wide band gap semiconductor such as TiOx, NiOx, or ZnO is used to provide the passivation on silicon. The contact stack consists of silicon (heavy or lightly p or n type doped or undoped), followed by a specific wideband gap semiconductor conducive to the contact as described herein which is followed by chosen metal. Wide bandgap semiconductors have specific charge neutrality level (CNL) which refers to an energy level in the band gap of the material, and where an abutting metal tends to line up its Fermi level independent of metal's vacuum level work function.

For a contact to n-type silicon, where electrons need to flow through the contact at lower resistance, a wide band gap material with a CNL close to the conduction band of silicon may be selected. For example, TiOx may be an ideal material for this application as TiOx has a conduction band which almost lines up with silicon while there is a large band discontinuity with silicon in the valence band. The CNL level of TiOx is very close to its conduction band edge which also happens to be close to the conduction band edge of silicon. When a metal such as Al or Ti is deposited on top of TiOx, the metal's work function lines up with the CNL of TiOx, thus creating a very small to non-existent barrier for electrons, thus allowing a very low contact resistance for electrons. The extent to which the metal work function approaches and gets close to the CNL may depend on the thickness of TiOx-for example, as TiOx gets thicker the metal work function gets closer to its CNL. Typically, in some instances 2 to 3 nm of TiOx pulls the work function of metal close to its CNL. On the other hand, because of a large valence band discontinuity with silicon, TiOx provides an excellent rejection barrier for holes (which are not wanted inside n-type contacts). Thus, holes approaching this interface are impeded and rejected with a very high probability, keeping them inside the silicon and giving them a chance to move towards and get into the p-type contact (which constitutes photocurrent). TiOx when annealed or in the presence of Ti (on top) becomes oxygen deficient. This creates oxygen vacancies, which in turn have an effect of doping TiOx such that it becomes an n-type semiconductor and leads TiOx to become conductive. Additionally, the resistivity of TiOx may be as low as 1 e-2 ohm-cm range.

As with the insulating passivating contact (Type I), an optimal thickness of TiOx may minimize contact resistance. This optimum occurs because as thickness increases the metal's Fermi level gets closer to CNL of TiOx which lowers the tunneling barrier for electrons. On the other hand, a too thick TiOx layer presents a high resistance tunneling barrier. Unlike the insulating barrier, the optimal thickness of minimum contact resistance tends to be larger because of the conductivity of TiOx. Other wide band gap semiconductors which have CNL close to the conduction band of silicon and which allow for high quality tunneling for electronics may also be used for this purpose.

For a p-type contact, a suitable wide bandgap material is a material such as NiOx. NiOx valence band tends to line up with the valence band of silicon, with a CNL also being close/approximate to this level—thus providing a good conduction path for holes. On the other hand, because of a much larger band gap than silicon (in the range of approximately 3.3 eV) there may be a large band discontinuity in the valence band. Thus, electrons in the silicon which impinge on this interface from the silicon side may see a very large barrier and have a high rejection. As with TiOx, there is an optimal thickness of NiOx which minimizes the contact resistance. A suitable metal on top of NiOx is Ni, for example.

TiOx and NiOx may be deposited using, for example, atomic layer deposition (ALD). Solar cell metallization on top of n-type may be, for example, Al and Ti which may be deposited using a myriad techniques such as physical vapor deposition, inkjet, and screen printing. Solar cell metallization on top of p-type contact may be, for example, Ni and may also be deposited using techniques such as PVD or inkjet.

Combination of wide bandgap and insulating materials. Another class of passivated contact solutions for a solar cell in general and a thin back contact back junction solar cell is a combination of an insulator and wide bandgap semiconductor formed as a thin sandwich layer between metal and silicon (referred to herein as Type III passivated contacts or combination contacts). As previously, the silicon may be heavily, lightly, or undoped and can be of either p or n-type. Choice of the metal and the combination stack should be catered depending on the doping of the silicon. Thus, the contact consists of a silicon layer, followed by an insulator layer, followed by a wide band gap semiconductor of the type conducive to the specific contact, and a metal (solar cell metallization) on top (also appropriately chosen for a good contact resistance).

Often there is a tradeoff between the passivation quality and contact resistance in a passivated contact based on thickness of the sandwich layer. Thus having a combination of a thin insulator and a wide band gap semiconductor opens up the process window between these two desirable metrics. For example, it is found that depositing a thin TiOx (wide bandgap) layer on top of a very thin Al2O3 (insulator) results in an improved passivation quality. The contact resistance may still be very desirable because TiOx is conductive and its thickness is still small. For example, in this case the carriers will tunnel through the insulator and will travel in the conduction band of TiOx.

Materials such as, for example, Al2O3/TiOx followed by Ti or Al may be used as the stack for an n-type contact. Whereas, materials such as, for example, Al2O3/NiOx/Ni may be the stack for p-type contact. Alternatively, for example, HfOx may also be considered in place of Al2O3 for the combination stack. And ZnO on top of HfOx or Al2O3, for example, may be used for an n-type contact. Combination passivation stack details may be found in U.S. patent application Ser. No. 14/538,760 filed Nov. 11, 2014 which is hereby incorporated by reference in its entirety.

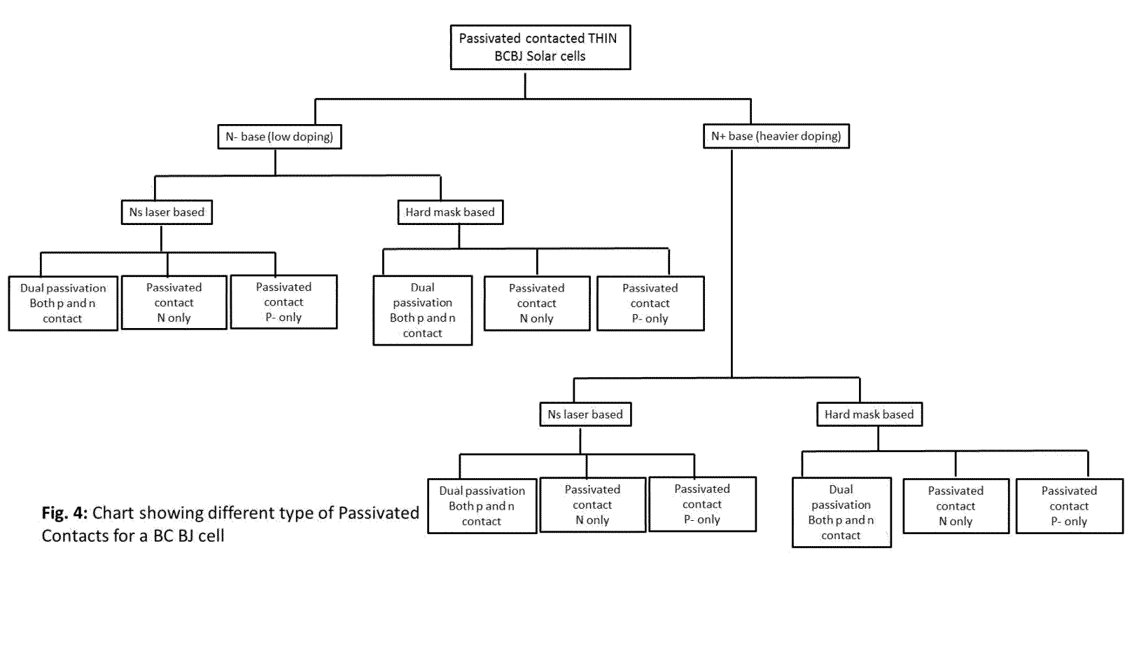

FIG. 4 is a schematic diagram of passivated contact solution embodiments and fabrication process flows described herein. As shown in FIG. 4, at a top level categorizes devices which use lightly doped n doping for the base contact along with a heavily doped p-type (emitter)—shown as N− base (low doping) in FIG. 4—and solar cells which need a heavily doped n (e.g., phosphorous or arsenic) doping for the base contact along with a heavily doped p-type contact (emitter)—shown as N+ base (heavier doping) in FIG. 4. Within each of these categories there are flows using laser processes for carving out and defining the different base and contact areas (shown as Ns laser based in FIG. 4) and additional sets using hardmask and wet process to achieve the same result (shown as hard mask based in FIG. 4). In the hard mask solutions, a laser may be used to define the mask to reduce or eliminate damage to the silicon substrate as ablation is performed away from the silicon surface. The last or lowest level is categorized by whether the passivated contact is used for either n or p contacts or both n and p contacts. These variations as well as several other sets of variations, such as Type I, II, and III contacts, are described herein.

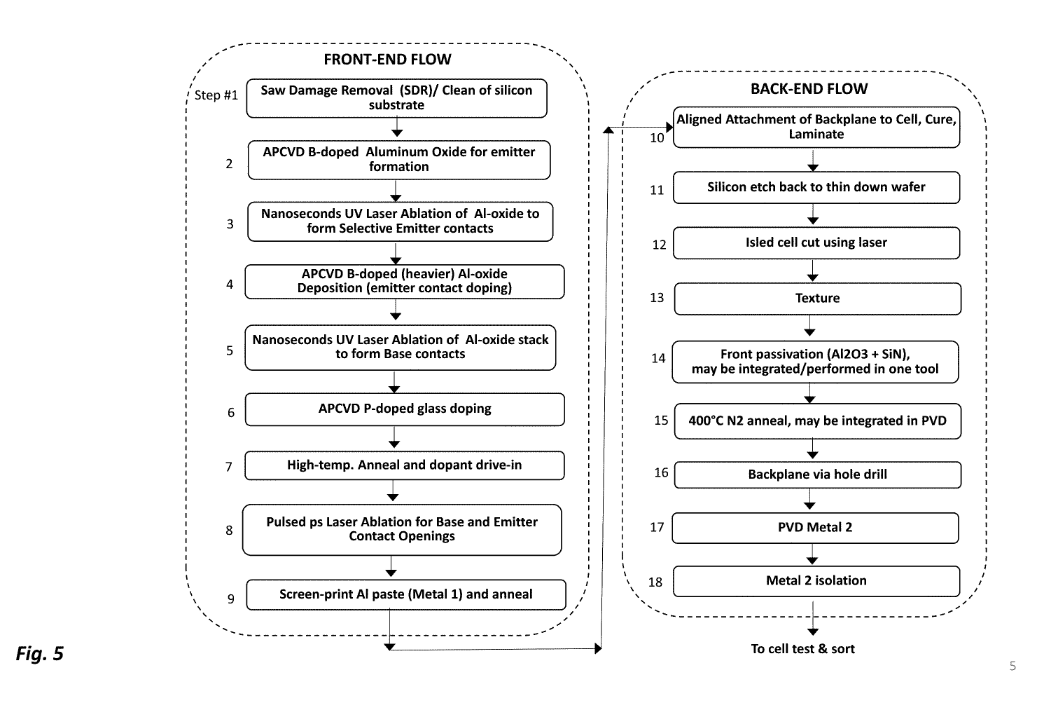

FIG. 5 is a representative non-passivated contact process flow for the fabrication of a thin backplane supported back contacted back junction cell which uses APCVD Al2O3 passivation on the cell backside (or non-sunnyside) for emitter formation and either ALD or PECVD AL2O3 passivation for frontside (i.e., the cell light receiving or sunnyside) passivation and is provided for reference. The process flow follows a structure suitable for making a thin silicon solar cell using backplane and dual level metallization, such as that described in detail in U.S. Pat. Pub. No. 2014/0318611 published Oct. 30, 3014 which is hereby incorporated by reference in its entirety. This includes laminating a backplane such as a prepreg material (step 10), using the prepreg to etch the silicon back and thin it down to a desired thickness such that it becomes conducive to high efficiency (step 11), using laser to isolated sub-cells on the solar cell (step 12) which is described in detail in U.S. Pat. Pub. No. 2014/0326295 published Nov. 6, 2014 and referring to the act of isolating several individually functioning smaller area solar cells held together cohesively by the prepreg after isolation.

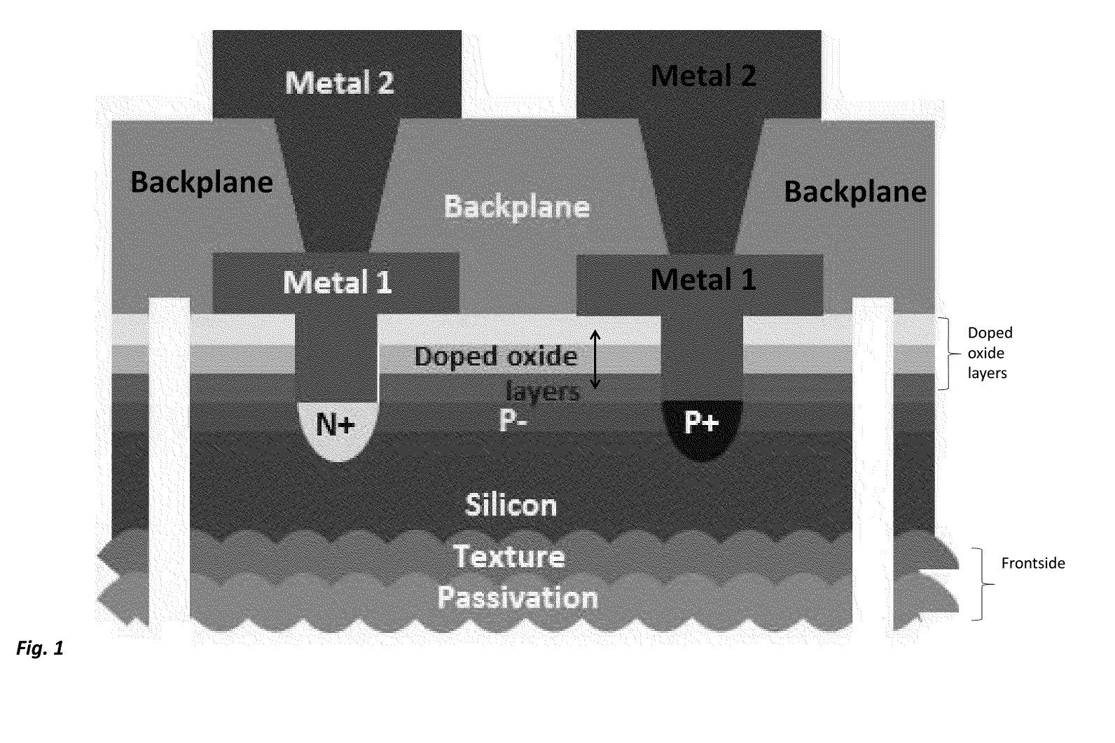

The flow of FIG. 5 is divided into the front-end and the back-end. The front end of produces a selective emitter where an aluminum based metal 1 contacts directly on heavy diffusion of both n and p-type, and non-passivated contacts and may result in the fabrication of a cell such as that shown in the cross-sectional diagram of FIG. 1. Aspects of this flow are described in detail in U.S. patent application Ser. No. 14/570096 filed Dec. 1, 2014 which is hereby incorporated by reference in its entirety. The present application provides solutions to the front-end of the process flow (before lamination in FIG. 5) including process flows highlighting passivated contact structures and methods.

With reference to FIG. 5, subsequent to metallization, the back-end of the process flow follows a structure suitable for making a thin silicon solar cell using backplane and dual level metallization, such as that described in detail in U.S. Pat. Pub. No. 2014/0318611 published Oct. 30, 3014 which is hereby incorporated by reference in its entirety. This includes laminating a backplane such as a prepreg material (step 10), using the prepreg to etch the silicon back and thin it down to a desired thickness such that it becomes conducive to high efficiency (step 11), using laser to isolated sub-cells on the solar cell (step 12) which is described in detail in U.S. Pat. Pub. No. 2014/0326295 published Nov. 6, 2014 and referring to the act of isolating several individually functioning smaller area solar cells held together cohesively by the prepreg after isolation. Subsequent to the isled cell cut the cell may textured (step 13). The act of texturing may also remove debris and clears up any laser damage created by isled cell laser cut. Following texture, front passivation may be deposited using myriad techniques (steps 14 and 15). Subsequently, vias are drilled in the back using a CO2 laser at a very high speed (step 16). The vias stop at the underlying aluminum paste. This is followed by the final steps of 2^{nd} level metal deposition (Metal 2 or M2) for example by PVD and Metal 2 patterning using laser (both shown steps 17 and 18). In some instance the deposited metal may be aluminum followed by nickel. M2 thickness may be in the range of 2 to 6 um as dictated by the needs of the design. The M2 patterning laser may, for example, be a nano second green or UV laser.

As noted previously, the present application provides solutions to the front-end of the process flow (before lamination in FIG. 5) to show various methods of forming passivated contacts. Table 1 shows the front-end of the process flow for making a passivated contact (insulator/metal based) thin backplane supported back contact back junction solar cell. The passivated contact scheme used is with an insulator such as Al2O3 or HfOx using ALD with either Ti or AL on the n-type base and Ni on the p-type emitter.

TABLE 1
FRONT-END FLOW (ns laser) Dual passivated
contact on both n and p contacts.

| | |
|---|---|
| 1 | Saw damage removal (SDR) |
| 2 | APCVD Boron doped Al2O3 for emitter formation |
| 3 | Nano second UV laser: Define base and emitter contact areas |
| 4 | Pico second laser on base only to remove the Al2O3 residual layer |
| 5 | High Temperature Anneal and dopant drive |
| 6 | Wet etch residual layer of Al2O3 and surface prep. + HF dip |
| 7 | ALD Al2O3 or HfOx |
| 8 | Ink jet Ni on emitter and Al on base + activate |
| 9 | Screen print Al Paste + activation (only if needed) |

The process flow of Table 1 is described in the context of an n-type wafer which is thinned down later in the backend flow to a thickness optimized to give best possible efficiency (for example thinned to a thickness less than 100 um). Innovative aspects are applicable to a p-type wafer as well with corresponding changes understandable to a person skilled in the art.

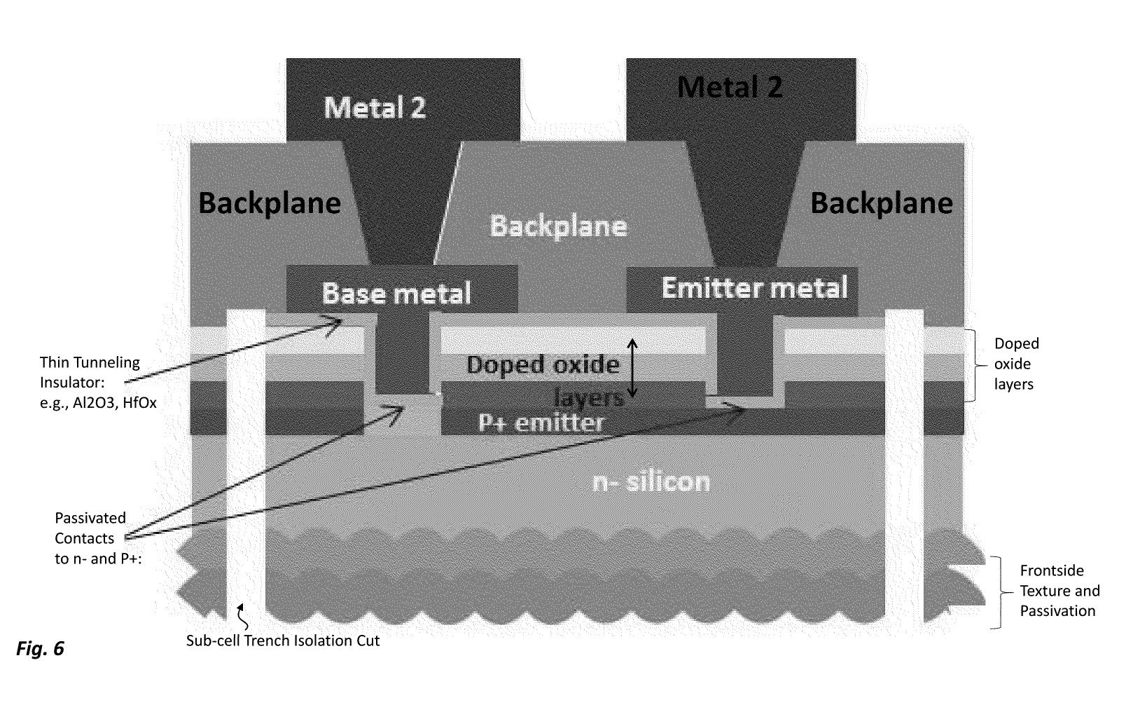

FIG. 6 is a cross-sectional diagram of an exemplary passivated contact thin backplane supported back contact back junction solar cell such as that which may fabricated according to the process flow of Table 1. The particular solar cell of FIG. 6 has passivated contacts on P+ area and n-− area and a first level metal having corresponding different base metal and emitter metal. Note, in this embodiment both base and emitter contacts are passivated and the passivation scheme is Type I. The contact is to n− surface and p+ surface and the insulating material (shown as Al2O3 or HfOx in FIG. 6) may have a thickness in the range of approximately 0.5 to 3 nm. FIG. 6 is a cross-sectional diagram of an exemplary solar cell such as that which may fabricated according to the process flow of Table 1.

Importantly, in the instance of either base passivated contacts only or emitter passivated contacts only metal one may be the same material. For example, an n type substrate having passivated base contacts only utilizing Al2O3 and an aluminum M1 layer with patterned electrically isolated base and emitter metallization. In other words patterned aluminum may be deposited using screen printing or other means such as inkjet or aerosol printing. PVD Al may also be used which is followed by patterning (e.g., by laser) to carve out the base and the emitter metal patterns.

With reference to Table 1, after saw damage removal SDR is performed on the silicon substrate in step 1 (e.g., a CZ wafer or in some instances an epitaxially grown silicon layer not requiring saw damage removal) an APCVD layer of Al2O3 is deposited in step 2. This layer is doped with boron such that it serves as the dopant source. In the given example of the process flow in Table 1, this layer is shown as a boron doped Al2O3, however, it may also be a material such as a boron doped SiOx layer which can also be deposited using APCVD. The dopant source is patterned with a UV ns laser to open both emitter and base contact areas in step 3. Nano second UV may be advantageous as it may create reduced to zero damage to the bulk silicon when used with certain class of APCVD Al2O3 films. If a boron doped SiOx layer is deposited using APCVD, a pico second laser may be required for patterning instead of nano second laser. And although damage in bulk silicon may result, this damage may be repaired to an extent by wet etching silicon after opening it with the pico second laser. Nano second UV laser when ablating a doped AL2O3 APCVD layer may leave behind a residue having a thickness of approximately 4 nm of doped but silicon rich, non-stoichiometric AlOx. The layer thickness is relatively well controlled and uniform as the ablation threshold of the interfacial Al2O3 layer increases dramatically with slightly increasing silicon content in it. This residual layer, while useful to serve as the p-type dopant source for the emitter contact, may be fully removed for the n contact area to form a contact to a pristine n− substrate. This may be achieved using a pico second laser (known to completely ablate AL2O3 without leaving a residue in some instances) on the n-type base contact area as shown in step 4 of Table 1. The emitter contact area is left untouched by the pico second laser and thus the emitter contact area retains a residual 4 nm Al2O3 layer. The amount of power used with pico second may be low enough that it does not create damage to the silicon. In high volume manufacturing the pico second and the ns lasers may be combined in a single laser tool. Subsequent to this ablation, a high temperature anneal is performed to drive the boron dopant in the patterned areas as shown in step 5 of Table 1. As a result of the ns and the selective pico second on the base, the back surface is continuously doped with boron except where there is base contact open as the pico second laser completely removed Al2O3. The amount of doping in the emitter contact area may be lower than the rest of the emitter as the thickness of the dopant source, (e.g., Al2O3) is approximately 4 nm in these areas. However, the doping concentration is still large/high enough to make a high quality contact with a tunneling insulator/metal combination on top.

After anneal and boron is driven in everywhere except in the base contact open area, a wet etch is deployed to remove the approximately 4 nm residual Al2O3 layer from the emitter to make the area pristine for a thin insulator deposition (as shown in step 6 of Table 1). Note, if slight undercut during the wet etch occurs this is not of high consequence. During the same wet etch, surfaces are prepared using either an HF last process. This is followed by the deposition of a thin insulator layer which goes everywhere including in the base and emitter contact open as well as in the field area (as shown in step 7 of Table 1). Insulator layer materials include materials such as Al2O3 and HfOx and may be deposited using techniques such as atomic layer deposition ALD, for example. Alternative high quality passivation insulators may also be used, for example deposited using ALD. As described with reference to Type I passivated contacts, a thin layer of insulator unpins the Fermi level of the overlying metal and takes the metal to its vacuum work function. An optimal insulator thickness in the range of 0.5 nm to 3 nm may minimize contact resistance and maximize passivation quality dependent on device requirements additional considerations and device.

Following the insulator deposition solar cell metallization (also referred to as a first level metal, metal 1, or M1) is deposited as shown in step 8 of Table 1. An ideal metal for the base contact is a metal with a vacuum work function close to the conduction band of silicon—for example metals such as Al and Ti. An ideal work metal for the emitter contact is a metal whose vacuum work function is close to that of valence band in silicon—for example metals such as Ni. Metals may be deposited on the base and the emitter contact areas using various deposition schemes. For example, patterned deposition schemes such as inkjet or Aerosol and screen prints may be advantageous to reduce process steps (i.e., metal patterning is not required). However, PVD based metal deposition may be used as well. As shown in the metallization scheme of Table 1 step 8, inkjet printing is used to print patterned Al on top of the n-type base area and patterned Ni on the p-type emitter area. This is followed by the thermal treatments to activate the two films. Note in some instances the thermal treatments may be sequential depending on the temperature requirements. Typically this may constitute the end of the front-end process flow and a common back-end process flow such as that provided in FIG. 5 may subsequently be deployed to complete the solar cell. However, in some instances a thicker metal 1 layer may be utilized to create a superior via drill stop layer for the via drill step during the backend process flow (FIG. 5). And in some instances a thicker metal 1 may also be used to improve the line resistance of the metal 1 layer. In these cases, a screen printed Al step with pads only under the via drill areas or with full lines can be added on top on metal 1 as shown in step 9 of Table 1.

VARIATION CLASS 1: There are several possible variants of metal 1. For example patterned inkjet Ni is deposited and activated on the emitter, this is followed by screen print Al on both base and emitter and activate. Or alternatively patterned Ni inkjet of the emitter is followed by a blanket PVD of Al. This may be followed by laser based separation of PVD Al (possible Ni on top to serve as ARC for laser) into isolated base and emitter lines. In yet another variation of metal 1 deposition, an all PVD deposition of Ni and AL and wet etch patterning may be used. Other combinations of screen printing, inkjetting (or aerosol printing), and PVD are implicit. After M1 metallization, backend processing, such as that described in FIG. 5, may be used to complete the solar cell.

VARIATION CLASS 2: In another variation shown in Table 2, only the base contact is opened before the high temperature anneal. This may ensure that there is no p-type dopant source where base contact is to be made with n− base. After the high temperature anneal and dopant drive, the emitter contact is opened using the pico second laser. Pico second laser may used to open as the Al2O3 film may be densified by the high temperature anneal and no longer conducive to being opened using a nano second (ns) laser. After both emitter and base contact are open and dopants are driven in, the surface is cleaned using HF to remove native oxide and ensure that the subsequent ALD deposited thin insulator (Al2O3 or HfOx) retains excellent surface qualities. Finally, metallization is performed as described previously including variants.

TABLE 2
FRONT-END FLOW (ns laser) Dual passivated contacts
on both n and p contacts.

| | |
|---|---|
| 1 | Saw damage removal (SDR) |
| 2 | APCVD Boron doped Al2O3 for emitter formation |
| 3 | ns UV laser: Define base contact area (remove p-type dopant) |
| 4 | High Temperature Anneal and dopant drive |
| 5 | pico second laser to open emitter contact |
| 6 | HF dip to prepare to clean the contact surface |
| 7 | ALD Al2O3 or HfOx |
| 8 | Ink jet Ni on emitter and Al on base + activate |
| 9 | Screen print Al Paste + fire |

VARIATION CLASS 3: Table 3 shows yet another embodiment of a front-end flow where only the base (n−) contact is passivated. The p+ emitter contact is the normal contact where metal is directly contacting silicon without any insulator in the middle. It is important to note subtle differences in metallization schemes. Because the emitter is not a passivated contact, direct aluminum may also work on a heavily doped p-type substrate—in other words first level metallization for base and emitter may be the same material, such as aluminum, with patterned electrically isolated base and emitter metallization. Alternatively, other choices for emitter are titanium and nickel. Base metal choice is similar as descried for the passivated contacts: aluminum and titanium. Similar variation may be produced where only emitter is passivated.

TABLE 3
FRONT-END FLOW (ns laser) Passivated contact only on n contact.

| | |
|---|---|
| 1 | Saw damage removal (SDR) |
| 2 | APCVD Boron doped Al2O3 for emitter formation |
| 3 | ns UV laser: Define base contact area, follow up with pico second |
| | laser to clean up if needed |
| 4 | High Temperature Anneal and dopant drive |
| 5 | HF dip to prepare to clean the contact surface |
| 6 | ALD Al2O3 or HfOx |
| 7 | pico second laser for emitter contact open |
| 8 | Screen print Al Paste + fire |

VARIATION CLASS 4: In yet another variation, hard mask and wet processing may be used to define the emitter and the base area as shown in the process flow in Table 4. Table 4 shows a front-end process flow for the fabrication of a thin backplane supported back contact back junction solar cell with dual passivated contacts using a hard mask.

With reference to Table 4, the first step is depositing a patterned undoped layer which may be used to block the boron dopants in only the specific area where base contact will be (step 2). The width of this patterned undoped layer may be approximately same as the intended width of the base contact and should cover all the areas where base contact is intended. The minimum thickness of the layer should be such that it completely blocks the boron dopant from the subsequent overlying doped oxide from going through to the silicon. For example, a SiOx layer may have a minimum thickness in the range of 50 to 100 nm, however the minimum thickness may be material dependent. On the other hand, the maximum thickness should be such that is it may be removed/taken off in subsequent processing without much difficulty. For example removal using a wet process should not cause significant undercut. Deposition methods include methods conducive to depositing patterned (or blanket followed by patterning) 50 nm to 500 nm thickness films in dimensions of approximately 70 to 100 um pattern width (e.g., interdigitated finger width). Undoped layer material selections include materials such undoped SiOx, other oxides, or nitrides deposited, for example, using methods such as inkjet and screen print.

Following the undoped layer, an APCVD based boron doped layer for emitter is deposited (step 3). This boron doped layer may be doped Al2O3 (as shown in Table 4) or a material such as boron doped SiOx. In some instances, doped Al2O3 layer may have an advantage of a superior emitter saturation current density. Note, although, doped Al2O3 still has the aforementioned advantage over a doped SiOx layer, in some instances it may be less advantageous to use Al2O3 in the case of hard mask plus wet processing (as shown in Table 4) as compared to the case of lasers used for patterning (as shown in Table 2). For example, when using lasers doped SiOx layer may be patterned only with a pico second laser which may damage the underlying silicon while in some instances using a laser patterned hard mask plus wet process there is minimal to zero damage to the silicon. Step 4 in Table 4 is a high temperature dopant drive from the overlying dopant source into silicon to from the p-type emitter areas. A key is that where the undoped layer is deposited, boron dopant is blocked and the surface remains n− in these areas. This is followed by step 5 which consists of a hard mask deposition. For example, this may be material such as PECVD deposited a-Si or a-Si/SIC (e.g., having a thickness in the range of 5 nm to 50 nm) and has two important properties: 1) it is conducive to being patterned by a pulsed laser into base and emitter without causing damage to the underlying silicon through the dopant source oxide; and 2) it is selective to wet etch used to pattern the underlying dopant source (e.g., an HF based etch chemistry). For example, hard mask materials such as PECVD a-Si and in some instances ALD deposited nitrides.

Step 6 in Table 4 consists of patterning the hard mask using a pico second laser. Pico second laser may be optimal to selectively ablate PECVD a-SI/a-SiC without going through the underlying dopant source. Step 7 consists of wet etching the dopant source in the base and the emitter areas using a-Si layer as the hard mask which protects rest of the area from being etched. Steps 8 and 9 consist of cleaning the surface to make it pristine (usually an HF dip) followed by deposition of the insulator layer such as Al2O3 or HfOx for a passivated contact, respectively. This is followed by metal deposition as shown in steps 10 and 11. Note that all variations of metal 1 deposition discussed in the context of Table 1 are equally applicable. After M1 metallization, backend processing, such as that described in FIG. 5, may be used to complete the solar cell.

TABLE 4
FRONT-END FLOW (Hard mask) Dual Passivated contact for both
emitter and base.

| | |
|---|---|
| 1 | Saw damage removal (SDR) |
| 2 | Print a patterned thin undoped blocking layer on the base only |
| | (ex. SiOx) |
| 3 | APCVD Boron doped Al2O3 for emitter formation |
| 4 | High Temperature Anneal and dopant drive |
| 5 | Deposit hard mask (Ex. PECVD a-Si) |
| 6 | Pico second UV laser to pattern only the hard mask for base and |
| | emitter |
| 7 | wet etch the underlying APCVD AL2O3 in emitter and APCVD |
| | Al2O3 + undoped oxide in base |
| 8 | HF dip to clean and prepare the contact surface |
| 9 | ALD Al2O3 or HfOx |
| 10 | Ink jet Ni on emitter and Al on base + activate |
| 11 | Screen print Al Paste + activation (only if needed) |

VARIATION CLASS 5: Note, a variation of the hard mask plus wet process is easily deducible from Table 4 when only one type of contact (either n or p-type) needs to be passivated while the other is still a direct metal to silicon contact.

VARIATION CLASS 6: Note, that all aforementioned passivated contacts to the base involved contacting a lightly doped (n− base). On a cursory examination, a contact to the n− region may be liable to present high resistance, however, the insertion of an appropriate insulator such as Al2O3 of HfOx may reduce the tunneling barrier sufficiently to yield low contact resistance even with n− substrate (e.g., to a resistance range of 1e15 to 1e17 range). However, if a lower contact resistance is required it may be possible to further improve the contact resistance by using a heavily doped n+ base layer with a passivated contact. This will entail creating a locally diffused n+ layer as a variation on the solar cell structure shown in FIG. 5. Three example process flows relating to this variation are provided in Tables 5 through 7. And while each flow uses laser based patterning and an extension to the hardmask process is readily deducible. Table 5 is an exemplary flow showing dual contact passivation to both p+ emitter and n+ base. Table 6 is an exemplary flow showing single contact passivation to base n+ only. Table 7 is an exemplary flow showing single contact passivation to p+ emitter only.

TABLE 5
FRONT-END FLOW (LASER) DUAL Passivated contact for BOTH
BASE and EMITTER, BASE Contact to N+.

| | |
|---|---|
| 1 | Saw damage removal (SDR) |
| 2 | APCVD Boron doped Al2O3 for emitter formation |
| 3 | nano second UV laser (followed by low ps to clean residue |
| | if needed): Define base window open (wider than the base |
| | contact for alignment) |
| 4 | APCVD phosphorous doped glass layer (dopant source for n+ base) |
| 5 | High Temperature Anneal and dopant drive |
| 6 | pico second laser to open base contact inside the base window and |
| | emitter contact simultaneously |
| 7 | Surface prep. and HF dip |
| 8 | ALD Al2O3 or HfOx |
| 9 | Ink jet Ni on emitter and Al on base + activate |
| 10 | Screen print Al Paste + activation (only if needed) |

Table 5 above shows a front-end process flow for making dual passivated contacts to both emitter and base, where the base is heavily doped.

TABLE 6
FRONT-END FLOW (LASER) Single Passivated contact for BASE
ONLY, BASE Contact to N+.

| | |
|---|---|
| 1 | Saw damage removal (SDR) |
| 2 | APCVD Boron doped Al2O3 for emitter formation |
| 3 | nano second UV laser (followed by low ps to clean residue |
| | if needed): Define base window open (wider than the base |
| | contact for alignment) |
| 4 | APCVD phosphorous doped glass layer (dopant source for n+ base) |
| 5 | High Temperature Anneal and dopant drive |
| 6 | pico second laser to open base contact inside the base window only |
| 7 | Surface prep. and HF dip |
| 8 | ALD Al2O3 or HfOx |
| 9 | pico second laser to open emitter contact |
| 10 | Screen print Al Paste + activation |

Table 6 above shows a front-end process flow for making passivated contact to base only, where base is heavily doped.

TABLE 7
FRONT-END FLOW (LASER) Single Passivated contact for EMITTER
ONLY.

| | |
|---|---|
| 1 | Saw damage removal (SDR) |
| 2 | APCVD Boron doped Al2O3 for emitter formation |
| 3 | ns UV laser (followed by low ps to clean residue if needed): |
| | Define base window open (wider than the base contact for |
| | alignment) |
| 4 | APCVD phosphorous doped glass layer (dopant source for n+ base) |
| 5 | High Temperature Anneal and dopant drive |
| 6 | pico second laser to open emitter only |
| 7 | Surface prep. and HF dip |
| 8 | ALD Al2O3 or HfOx |
| 9 | pico second laser to open base contact inside the base window |
| 10 | Inkjet Ni on the emitter and Al inkjet on the base |
| 11 | Screen print Al Paste + activation (only if needed) |

Table 7 above shows a front-end process flow for making passivated contact to emitter only, where base is heavily doped.

It is important to note that the metallization scheme may change depending on whether both contact are passivated or whether one of the other is passivated. When there is a passivated contact on top of p-type material, the overlying material should be a metal with work function close to valence band of silicon, such as nickel. When there is no passivated contact on p-type material, the overlying metal may be nickel, aluminum, or titanium. Similarly for the base a passivated contact should be a material such as aluminum or titanium. Non-passivated contacts increase metallization materials to include nickel in addition to aluminum and titanium. Within the above constraints, different variations on both the types of metals and deposition schemes may be used although not explicitly described. Further, hard mask and wet processing versions of the process flow for an n+ passivated contact may be readily understood from Tables 4, 5, 6, and 7.

VARIATION CLASS 7: In the aforementioned process flows, the dopant source layers (oxides of Aluminum and Si) are retained and become the permanent part of the solar cell. In fact, while most of the above dopant sources were APCVD based, dopings in the silicon may also be created using screen printed dopant pastes. However, it is readily understood that in all above embodiments the initial doping layers may be stripped off and passivation layers such as undoped Al2O3 or SiO2 may be deposited using methods such as ALD, APCVD, or PECVD. This deposition will be followed by either a wet etch (hard mask based) or laser based contact open. Subsequent to which, and along the lines of the flows described above, passivated contacts may be created on p-type, n-type or both types using ALD based AL2O3 or HfOx type insulators. PECVD deposition of these insulators may also be used for passivated contacts. In general and as described before, these contacts are readily applicable to both generic cases of when base is n− or heavily doped.

VARIATION CLASS 8: All aforementioned process flows are described in the context of Type I passivated contacts. Type I passivated contacts as defined earlier have a single thin insulating layer sandwiched between metal and the semiconductor. It is important to mention that in all of the above flows, type II and type III passivated contacts may also be used.

Inherently, it may be less complex to use Type II and Type III contacts (both of which contain a wide bandgap semiconductor) when only one of base and emitter needs to be passivated because the type of wide band gap semiconductor required for each contact type is different. When type II and type III contacts are used on both contacts, it is imperative to note that for electrons (n type areas) wide band gap semiconductors with CNL at conduction band either by themselves or in conjunction with a thin insulator such as Al2O3/HfOx should be used. For example, TiOx by itself or a combination of Al2O3/TiOx may be deposited in-situ in the ALD reactor and replaced by just Al2O3 or HfOx ALD. Whereas for the p-type contacts, for example, NiOx by itself or in conjunction with Al2O3 and HfOx should be the Type II and Type III passivating material. Additionally, it should be noted that when both n and p-type contacts are passivated at the same time, because of the requirement of different wideband gap materials increased patterning of the wide band gap material may be required to put both kinds in the right places. This may add process flow steps and fabrication complexity. Thus, for dual passivated contacts type I passivated contacts may be advantageous. For a single passivated contact (either on base or on emitter), because wide band gap material is conductive it also should be isolated in the field—isolation patterning readily performed with a laser.

As described previously, when an ns laser is used in conjunction with APCVD Al2O3 film it may leave a residual AlSiOx layer at the interface—for example in some instances a residual AlSiOx layer approximately 4 nm to 10 nm thick. And as described previously, this residual AlSiOx layer may be removed using a low powered pico second laser or using wet etch.

Additional process flows are provided with respect to Variation Class 3 shown in Table 3 and which describes only a cell n− contact being passivated. Table 3 is reproduced below as Table 8 with additions including: 1) in addition to pico-second laser clean up, wet clean-up of the residual layer is included; and 2) metallization includes PVD Aluminum or other methods of depositing patterned Al or depositing Al and subsequent patterning (e.g., with laser or with wet etch or with screen printed etch paste).

An advantage of using only single passivated (e.g., n− contact) contact as compared to dual passivated contacts is that relating with single passivated contact only one type of metal is needed (e.g., aluminum or titanium) as compare to two different metals for base and emitter—an advantage which lends to simplified fabrication and integration processes.

The following categories are identified in terms of structure and methods for n− contact only passivated structures:

1. Non-selective emitter.

2. Selective emitter (SE).
a. SE formed using laser doping of Al, also known as Laser fired contact (LFC).
b. SE formed using laser doping of doped dielectric, referred to as Laser doping (LD).

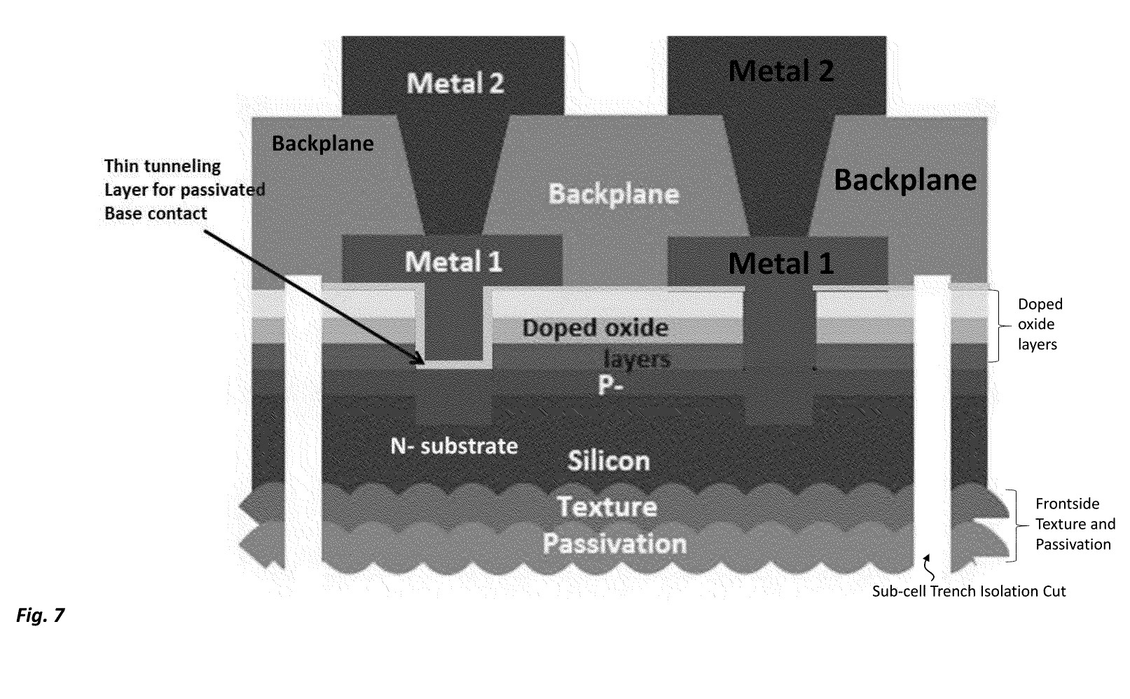

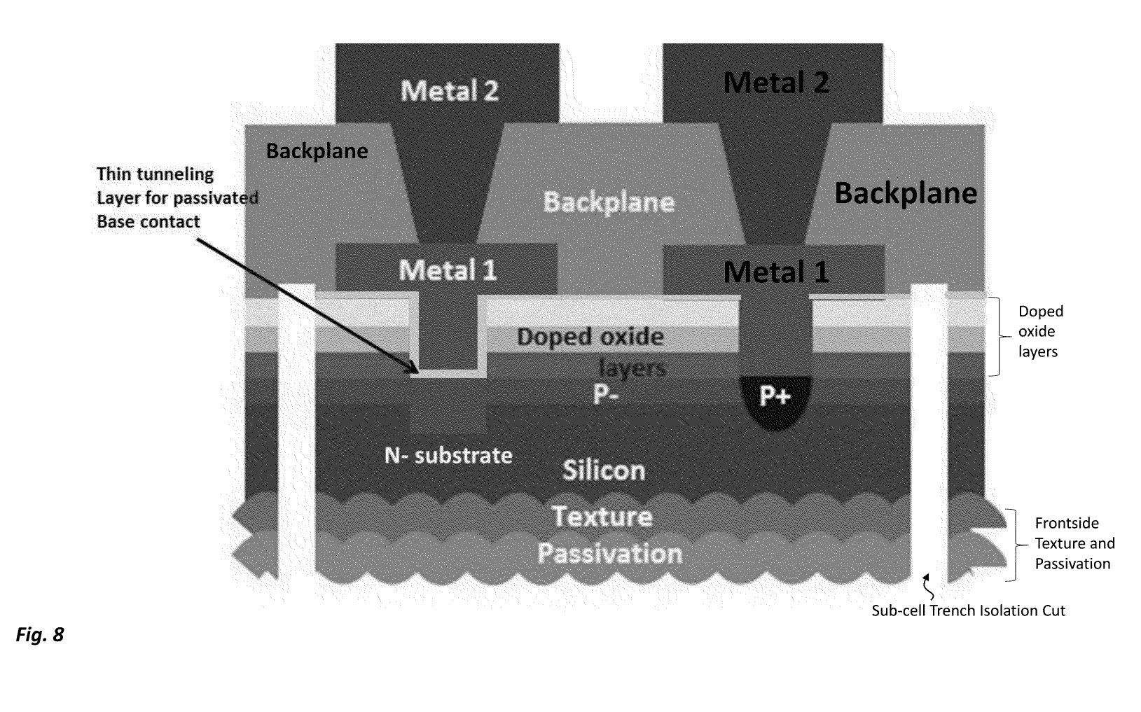

FIG. 7 is a cross-sectional diagram of a backplane supported thin back contact back junction isled solar cell (similar to the structure of FIG. 6) having passivated n− base contact and having non-passivated contact, non-selective emitter (for emitter side)—in other words a passivated base contact and non-passivated non-selective emitter solar cell. FIG. 8 is a cross-sectional diagram of a backplane supported thin back contact back junction isled solar cell (similar to the structure of FIG. 7) having selective emitter and passivated base contact—in other words a passivated base contact and non-passivated selective emitter solar cell. And although, these structures are shown in the context of a backplane supported thin solar cell, they may be equally applicable to a thicker back contact back junction solar cell with no backplane as well as applicable to isled (a master cell having sub-cells) and non-isled solar cell structures. The doped oxide layers of FIGS. 6, 7, and 8 is a generic placeholder referring to numerous dielectric layer variations which may be catered according to specific process flow requirements for example considerations dictated by Jo emitter and fabrication considerations such as the ability for laser oxide ablation. For example, in one instance doped oxide layers may be a combination of boron doped Al2O3 and undoped Al2O3 or undoped SiOx. In some instances boron doped Al2O3 may be advantageous as it is etch resistant to certain chemistries such as Hf. In another instance, for example, doped oxide layers may be a boron doped SiO2 (BSG) and undoped SiO2 combination.

Note, in the structures of FIGS. 7 and 8 there is a thin tunneling/passivation layer covering the n− region. In one embodiment this thin tunneling/passivation layer covering the n− region may be deposited using atomic layer deposition (ALD) and may be Al2O3 or Hf Ox and other metal oxides either in single or bilayer combinations capable of providing high quality passivation and high quality tunneling contacts.

Table 8 shows representative process flow to make a passivated base contact without a selective emitter—in other words a non selective emitter flow. Table 8 and the following process flows describe only the front-end process flow while representative back-end process flow is described above.

TABLE 8
Passivated n− contact with Non-selective emitter.

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | HF dip to prepare to clean the contact surface |
| 6 | ALD Al2O3 or HfOx or any other tunneling material with good |
| | passivation quality |
| 7 | laser for emitter contact open (For example with pico second laser) |
| 8 | PVD (sputtering or evaporation) Aluminum (inkjet or screen print |
| | is also possible) |
| 9 | Patterning of metal into base and emitter (not required with screen |
| | print or inkjetting |

Table 9 shows a front-end process flow converting the flow of Table 8 into a selective emitter flow using laser fired contact (LFC).

TABLE 9
Passivated n− base contact with Selective emitter using laser fired contact
(LFC).

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | HF dip to prepare to clean the contact surface |
| 6 | ALD 1. Al2O3 or 2. HfOx or 3. SiO2, or 4. Al2O3 + TiOx, or 5 |
| | SiO2 + TiOx |
| 7 | PVD (sputtering/evaporation) of Aluminum (inkjet, screen print, or is |
| | also possible) |
| 8 | Laser fired contact (LFC) of Al metal to form selective emitter only |
| | in the emitter areas |
| 9 | Patterning of metal into base and emitter (not required with screen |
| | print or inkjetting |

Note, in the selective emitter with passivated base contact using LFC of Table 9 above, the ALD material of Step 6 may be any material which makes a high quality tunneling contact to n− and is a high quality passivation layer. And although various single and bi layer examples are provided in Table 9, these should not be interpreted as limiting but only exemplary material possibilities. Generally an infra-red nano second laser may be used for laser fired contact (LFC) Step 8 although other lasers may also be used such as a green nano second laser.

Importantly, and as can be seen, the front-end process shown in Table 9 is self-aligned.

In the flow of Table 9, relating to LFC (Step 8) one possible variation is that an emitter contact is opened explicitly first using a laser (e.g., pico second laser) which is followed by PVD Al and a laser step where AL is driven into the emitter to form a selective emitter, deeper doping, under the contacts.

Table 10 shows a process flow where selective emitter is made using laser doping. Steps 1 through 6 of Table 10 are identical to that of the flow described in Table 9. After ALD of the base passivation layer (Step 6) laser is used to drive boron and/or Al directly from the dielectric into the silicon to form a deeper p+ doped selective emitter. Typically, this process also opens the dielectric—hence, metal may be deposited directly after this step in a self-aligned fashion (doping is aligned with the contact open). In the case of a sporadic dielectric remaining, in a variant of the flow, the laser doping step may be immediately followed by a contact open on the emitter step, before the metal deposition. Typically, laser doping may be performed using a nano second flat top green laser. Table 10 below shows a selective emitter flow with passivated base contact using laser doping.

TABLE 10
Passivated n− contact with selective emitter (by laser doping of BSG or
Boron doped Al2O3 in n− regions of emitter).

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | HF dip to prepare to clean the contact surface |
| 6 | ALD 1. Al2O3 or 2. HfOx or 3. SiO2, or 4. Al2O3 + TiOx, or 5 |
| | SiO2 + TiOx |
| 7 | Laser doping of Boron/Al from doped APCVD Al2O3 into Silicon |
| 8 | PVD (sputtering or evaporation) Aluminum (inkjet or screen print is |
| | also possible) |
| 9 | Patterning of metal into base and emitter (not required with screen |
| | print or inkjetting |

Table 11 shows a selective emitter flow with passivated base contact using laser doping of ALD AL2O3. The process of Table 11 uses the aluminum in the atomic layer deposited undoped Al2O3 to dope the underlying silicon.

TABLE 11
Passivated n− contact with selective emitter (by laser doping of ALD
Al2O3 in p+ regions of emitter).

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | pico second laser for emitter contact open |
| 6 | HF dip to prepare to clean the contact surface |
| 7 | ALD Al2O3 |
| 8 | Laser doping of Al using ALD Al2O3 on emitter only to form |
| | selective emitter |
| 9 | PVD (sputtering or evaporation) Aluminum (inkjet or screen print |
| | is also possible) |
| 10 | Patterning of metal into base and emitter (not required with screen |
| | print or inkjetting |

Table 12 shows a selective emitter flow with passivated base contact using laser doping of ALD AL2O3. In the Table 12 flow the emitter contact is opened before the high temperature anneal so that any residual damage may be healed by the anneal. An additional difference is that the Al metal is deposited after ALD Al2O3 and before the laser doping which allows Al to be driven in to silicon from both metal and from the ALD layer.

TABLE 12
Passivated n− contact with selective emitter (Laser doping using
ALD film).

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | pico second or nano second laser for emitter contact open (followed |
| | by wet etch if needed) |
| 5 | High Temperature Anneal and dopant drive |
| 6 | HF dip to prepare to clean the contact surface |
| 7 | ALD Al2O3 |
| 8 | PVD (sputtering/evaporation) of Aluminum (inkjet, screen print, or |
| | is also possible) |
| 9 | Laser fired contact (LFC) of Al metal to form selective emitter only |
| | in the emitter areas |
| 10 | Patterning of metal into base and emitter (not required with screen |
| | print or inkjetting |

In the process flow of above and Tables 8 through 12 particularly, contact area may be adjusted as needed for the base. And because base contact is passivated there is more flexibility in increasing the base contact area.

Additionally, the typical ALD tunnel oxide thicknesses may vary in the range from 0.5 nm to 30 nm for a single layer.

In the process flow of above and Tables 8 through 12 particularly, if necessary, a screen print of Al paste may be printed on top of patterned PVD metal to be used for an etch stop for the via drill process in backend processing.

In the process flow of above and Tables 8 through 12 particularly, the nano second laser for base opening may be substituted with a pico second laser. In this case the pico second laser may be used by itself to ablated oxide or it may be followed by wet etch to remove damage in silicon.

In the process flow of above and Tables 8 through 12 particularly, the APCVD layer which is doped Al2O3 may be substituted by a doped BSG layer. A doped BSG layer may be advantageous when used in conjunction with a pico second laser—in other words because pico second laser ablates both BSG and doped Al2O3, nano second laser may be advantageous on doped Al2O3 compared to BSG layer. However if a low density BSG layer is deposited it may equally capable of being ablated with a nano second laser.

In the process flow of above and Tables 8 through 12 particularly, an important variation substitutes the ALD dielectric layer passivated contact in the base by an amorphous silicon passivation followed by aluminum or ITO (indium tin oxide) plus aluminum. Typically, the a-Si may be made of intrinsic followed by n+ type having a thickness ranging from 5 nm to 15 nm-this layer provides excellent passivation and high quality contact to n− substrate. Tables 13 through 16 below show representative process flows for base passivated contacts using amorphous silicon passivation analogue with the non-selective emitter flow of Table 8, LFC of Table 9, and laser doping of Table 10, respectively.

TABLE 13
Passivated n− contact (a-Si) with non-selective emitter.

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | Surface preparation before a-Si |
| 6 | PECVD intrinsic and n+ a-Si |
| 7 | laser for emitter contact open (For example with pico second laser) |
| 8 | PVD (sputtering or evaporation) Aluminum (inkjet or screen print |
| | is also possible) |
| 9 | Patterning of metal into base and emitter (Pattern n+ a-Si to isolate |
| | at the same time) |

TABLE 14
Passivated n− contact (a-Si) with selective emitter using laser fired contact
(LFC).

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | Surface preparation before a-Si |
| 6 | PECVD intrinsic and n+ a-Si |
| 7 | PVD (sputtering/evaporation) of Aluminum (inkjet, screen print, or |
| | is also possible) |
| 8 | Laser fired contact (LFC) of Al metal to form selective emitter only |
| | in the emitter areas |
| 9 | Patterning of metal into base and emitter (Pattern n+ a-Si to isolate |
| | at the same time) |

TABLE 15
Passivated n− contact (a-Si) with selective emitter (by laser doping of
BSG or Boron doped Al2O3 in n− regions of emitter).

| | |
|---|---|
| 1 | Saw damage removal (SDR) |
| 2 | APCVD Boron doped Al2O3 for emitter formation |
| 3 | ns UV laser: Define base contact area, follow up with either |
| | 1. picosecond laser or 2. wet etch to clean up residual layer |
| 4 | High Temperature Anneal and dopant drive |
| 5 | Surface preparation before a-Si |
| 6 | PECVD intrinsic and n+ a-Si |
| 7 | Laser doping of Boron/Al from doped APCVD Al2O3 into Silicon |
| 8 | PVD (sputtering or evaporation) Aluminum (inkjet or screen print |
| | is also possible) |
| 9 | Patterning of metal into base and emitter (Pattern n+ a-Si to isolate |
| | at the same time) |

The disclosed subject matter provides amorphous silicon passivated contacts (referred to as ASP contacts) for back contact back junction solar cells and specifically interdigitated back contact back junction solar cells (IBC cells). ASP contacts are described with reference to the frontend and backend process flow variants herein.

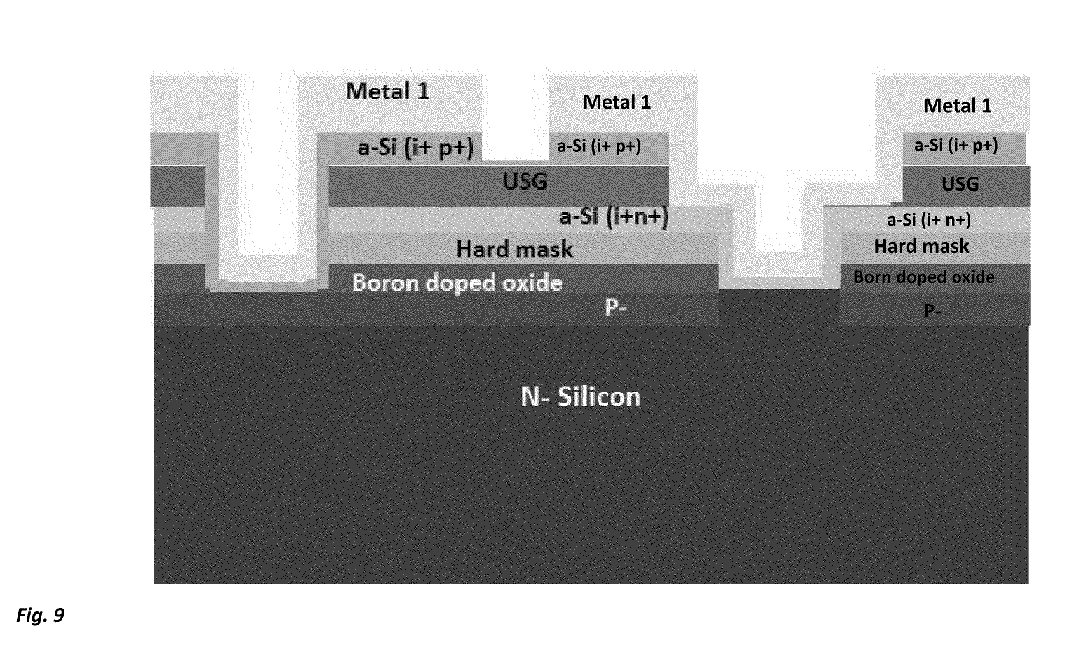

FIG. 9 is a cross-sectional diagram of a backplane supported thin back contact back junction solar cell (e.g., interdigitated back contact) having double amorphous silicon (a-Si) passivated contacts—in other words both p and n type contacts are passivated. The contacts for base and emitter of the cell in FIG. 9 are passivated with a-Si. FIG. 9 shows passivation using intrinsic a-Si/n+ a-Si combination for n-type contact, while intrinsic and P+ a-Si silicon combination for the p-type contact. Other parts of the films shown in FIG. 9 are process flow specific and should not be interpreted narrowly. Importantly, a-Si passivated contacts on either base or emitter or both are applicable to the back contact solar cells described herein.

In a variation of the structure shown in FIG. 9, the a-Si may only be intrinsic and common to both p and n-type without the doped a-Si on top of it. The success of this type of structure may depend on the contact resistance of the overlying metal with the intrinsic a-Si. If the metal workfunctions are chosen correctly the doped a-Si on top of intrinsic may be eliminated thus simplifying the process flow. This may require the n-type contact to have an overlying metal which has a workfunction close the conduction band of silicon (e.g., aluminum, titanium) and the p-type contact to have an overlying metal on top of intrinsic a-Si which has a workfunction close to the valence band of silicon (e.g., nickel).

Advantages of amorphous silicon passivated contacts include, but are not limited to: reduces or in some instances eliminating the Jo of contacts, thus allowing to increase Voc to greater than 730 mV in some instances; obviating the need to open the contacts, thus removing laser damage to the bulk film caused by contact opening (if lasers used for contact opening); results in very large emitter fraction compared to a standard IBC cell including heterojunction with intrinsic thin layer (HIT) cells; improved charge collection because most of the forward bias voltage drop is still on the diffused P-N junction and relatively very little charge collection on the P+ crystalline vs. P+ a-Si junction, thus resulting in better current collection.

Generally, high quality solar cell contacts should have a superior interface of a-Si with crystalline silicon n-type and p+ type, excellent contact resistance between c-si and a-Si on both contacts, and excellent contact resistance between doped a-Si (n+ and p+) and the metal.

With reference to FIG. 4, amorphous silicon passivated contacts (ASP contacts) are applicable to several different back contact back junction solar cell categories. Again with reference to FIG. 4 categories, at a broad level passivation may be on a base contact area which is either n+ heavily doped or is lightly doped. Within each of these groups, there is a specific class of process flows where the base and emitter pattern definition is achieved using laser or it is based on using hardmask/wet etch, for example. In some instances a hard mask flow may be more expensive while in some instance a laser flow may cause damage to the silicon. The final category is based on whether both n and p-type contacts are passivated or only a single contact is passivated.

In addition to the above distinctions, amorphous silicon passivated contact process flows may be further distinguished by: 1) the process used to deposit a-Si; 2) the method used to isolate a-Si; and 3) the metal on top of a-Si.

Representative process flow deposition methods for amorphous silicon passivated contacts include: PECVD deposited a-Si for the contacts (in some instances the most common and proven deposition process), APCVD deposited a-Si for the contacts, and ALD deposited a-Si.

Representative process flow a-Si isolation methods include using laser or using wet etch.

Representative process flow metals include metal paste and PVD metal on top of amorphous silicon passivated contacts (ASP contacts). Depositing metal using PVD may further require metal patterning for example using laser metal ablation or wet etch.

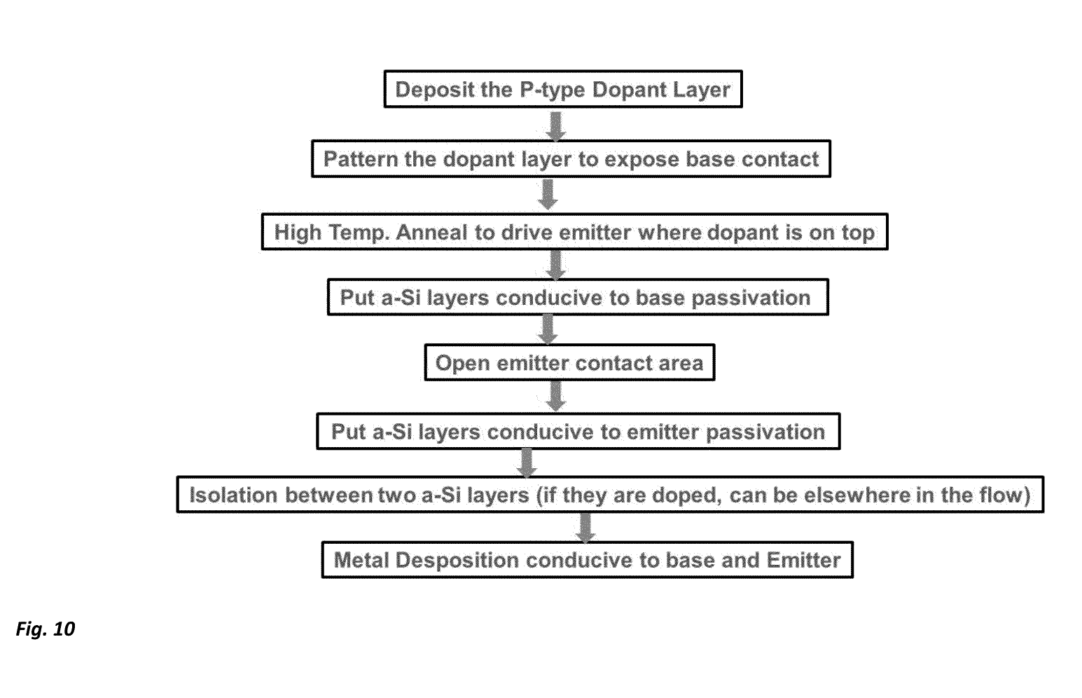

FIG. 10 is a front-end process flow which shows the front-end method to make an amorphous silicon passivated interdigitated back contact solar cell (ASP-IBC). Specifically, FIG. 10 shows a front-end method for making a dual passivated ASP-IBC having an n-type wafer and an undoped (n−) base contact. The process flow of FIG. 10 caters to making an n− base with dual passivation.

In FIG. 10 the first layer is the doped layer is the source of emitter doping. This layer generally may be, for example, either boron doped SiOx or a boron doped Al2O3. The advantage of boron doped Al2O3 is that under certain conditions it is conducive to being patterned with a nanosecond (ns) laser with negligible or zero laser damage to the underlying silicon. Al2O3 may also be an excellent passivation giving a low Jo of the emitter. The next step is to pattern this deposited layer to expose the base. In other words, when the dopants are driven in, the areas where this layer is patterned will not get boron and will remain the background n− doped. The patterning may be performed with lasers or also using wet etching using a permanently buried hardmask or a temporary mask which is removed subsequently. Within suitable laser patterning schemes, either picosecond laser (compatible with most oxide—both AL2O3 and BSG) or nanosecond laser (this needs a low density film such as that deposited using APCVD of Al2O3 at certain temperature) may be advantageous. And although in some instances pico second laser may create laser damage, the damage may be removed by a subsequent short silicon etch. In some instances nanosecond laser ablation tends to be relatively damage free for special low density films, but can also be augmented by a wet process if necessary. Next, the emitter is formed by driving boron from the dopant source into silicon using a high temperature step. Now base n− region is exposed and is passivate with a-Si. A stack conducive to passivating this type of silicon is an intrinsic a-Si (e.g., having a thickness in the range of 2-8 nm range) followed by an n+ doped a-Si layer (e.g., having a thickness in the range of 5-l5 nm). This doping allows a relatively low contact resistance, provides excellent passivation, and provides high rejection to holes. This step is followed by emitter contact definition and may be either selective emitter (heavier doping under emitter contact) or non-selective emitter kind

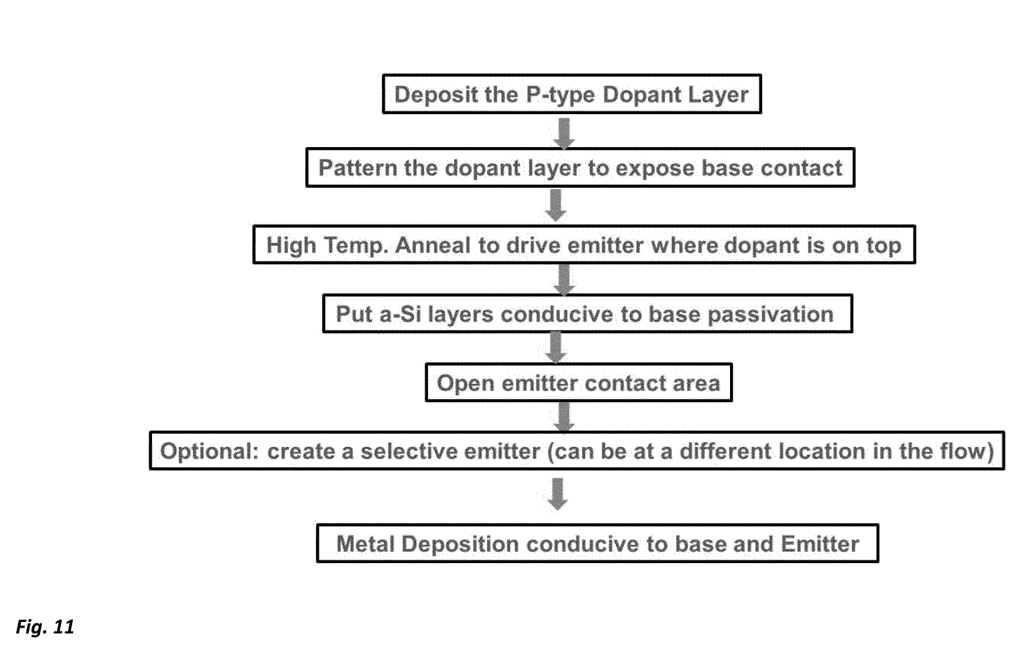

FIG. 11 is a front-end method for manufacturing a single passivated (n− base) with an n− base amorphous silicon passivated interdigitated back contact solar cell (ASP-IBC)—in other words a base passivated (n− base) ASP-IBC.

Table 16 shows a shows a process flow for passivating the emitter contact with a-Si. Specifically, Table 16 shows a process flow using laser based contact opening with a-Si passivation on the emitter only.

TABLE 16
a-Si contact on emitter only with n+ under base contact.

| | |
|---|---|
| 1 | SDR |
| 2 | APCVD BSG1 |
| 3 | Laser open to expose base (n+ doping area) |
| 4 | APCVD PSG to create n+ area |
| 5 | MRL |
| 6 | Laser open the emitter contact |
| 7 | Deposit i a-Si + p+ a-Si |
| 8 | Laser CO on PW + isolate a-Si base/emitter |
| 9 | Screen print metal/fire or PVD metal and base/emitter definition or |
| | Inkjet metal |

Note, as the a-Si contact is on the emitter as shown in Table 16, the a-Si consists of a dual layer or intrinsic and p+. In an alternative embodiment, the process flow of Table 16 may be modified to put the contact on a selective emitter if necessary. In the case of selective emitter, the doping under the emitter contact will be made heavier first, then a contact is open within that doping and a-Si is deposited on top of it. Also, for example, although Table 16 is described in the context of BSG and laser, this should not be interpreted in the limited sense and as note other contact opening schemes and emitter doping layers may be used.

Tables 17 and 18 show front end solar cell process flow where only base has a-Si passivation—in other words a-Si passivation on the base only. In this scenario, Tables 17 and 18 present two possibilities: 1) either the base is not heavily doped (as shown in Table 17) and the contact is made on the n− (note in some instances this will require a relatively large amount of contact area to make up for higher contact resistance); or 2) where the base is heavily doped and subsequently an a-Si passivation is deposited (as shown in Table 18). Table 17 shows a representative process flow for an n− base which passivates only the base contact with a-Si.

TABLE 17
a-Si contact on base only (n− base) with selective emitter.

| | |
|---|---|
| 1 | SDR |
| 2 | APCVD BSG1 (lighter emitter) |
| 3 | Laser open are for heavier selective emitter doping |
| 4 | APCVD BSG2 (heavier doping) |
| 5 | Laser open base area |
| 6 | High temperature anneal |
| 7 | Deposit i a-Si + n+ a-Si |
| 8 | CO on emitter only + isolate a-Si |
| 9 | Screen print metal/fire or PVD metal and base/emitter definition or |
| | Inkjet metal |

Table 18 shows a representative process flow for an n+ base which passivates only the base contact with a-Si.

TABLE 18
a-Si contact on base only (n+ base) with selective emitter.

| | |
|---|---|
| 1 | SDR |
| 2 | APCVD BSG1 (lighter emitter) |
| 3 | Laser open are for heavier selective emitter doping |
| 4 | APCVD BSG2 (heavier doping) |
| 5 | Laser open base area |
| 6 | Phosphorous doped glass (PSG) APCVD deposition |
| 7 | High temperature anneal |
| 8 | CO on base only |
| 9 | Deposit i a-Si + n+ a-Si |
| 10 | CO on emitter only + isolate a-Si |
| 11 | Screen print metal/fire or PVD metal and base/emitter definition or |
| | Inkjet metal |

Note, the process flows above and particularly the process flows shown in Tables 17 and 18 may use a hardmask instead of lasers. Additionally, these flows may utilize nano or pico second lasers for patterning. Additionally, in an alternative embodiment, each of these flows may be used to fabricate a non-selective emitter solar cell by removing the heavy BSG 2 open and deposition step (shown as Step 4 in Tables 17 and 18).

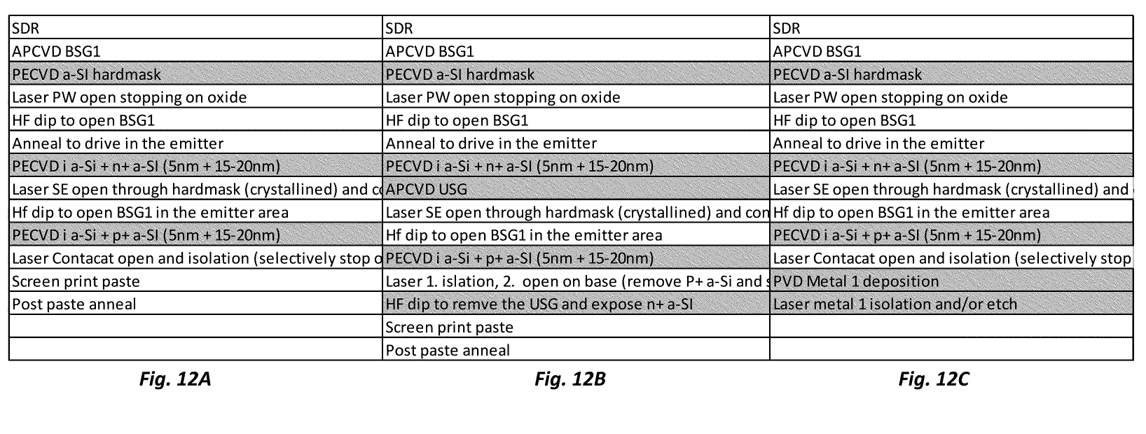

FIGS. 12A through 12C are front end solar cell fabrication flows where both base and emitter contacts are passivated with a-Si. Each one of the flows shown in FIGS. 12A through 12C uses PECVD to deposit a-Si and uses an a-Si based hard mask to pattern. Other a-Si deposition schemes such as APCVD (if available) are understood and may save steps when combined with APCVD oxide deposition steps. BSG is a representative material and may, for example, be substituted by doped Al2O3. In another embodiment, the doping layers may be stripped and an undoped Al2O3 layer may be deposited as a passivation. And although the process flows of FIGS. 12A through 12C are described using hard mask patterning scheme, laser patterning schemes may are also applicable.

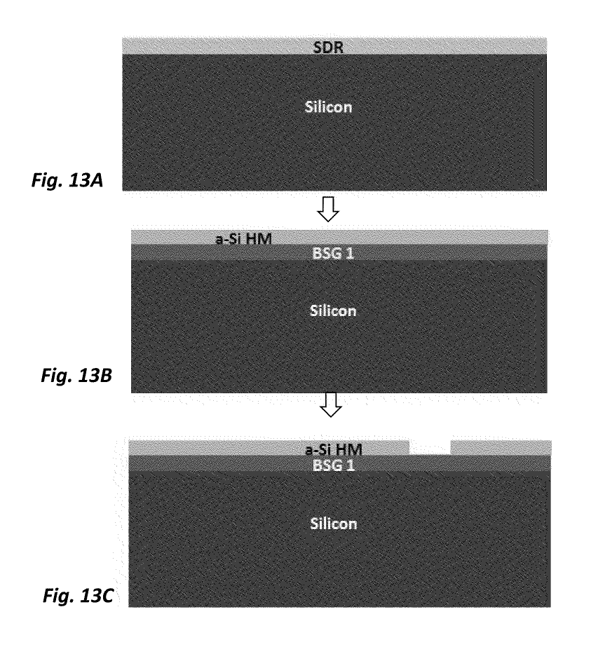

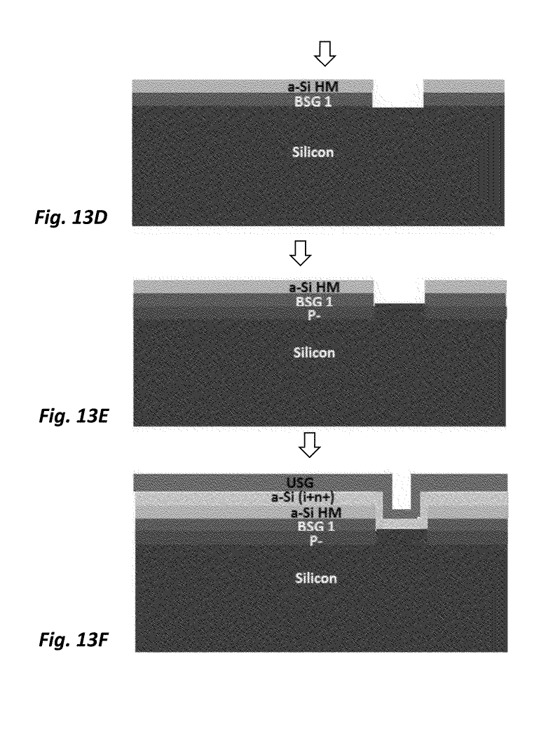

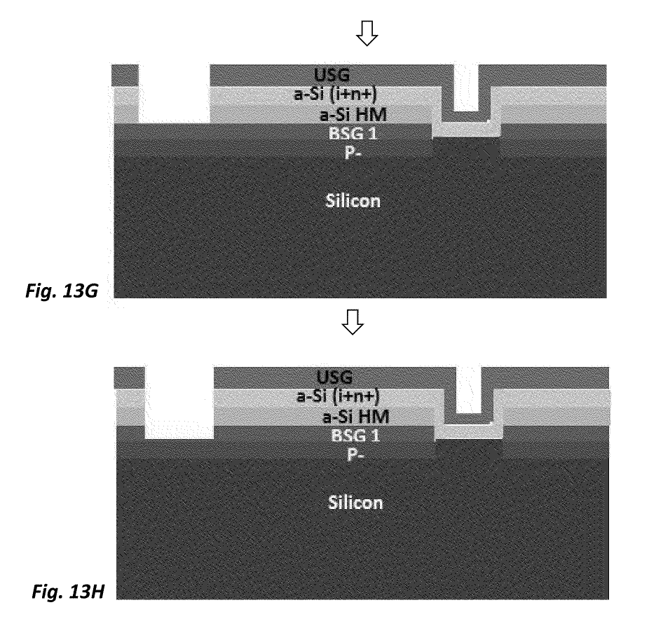

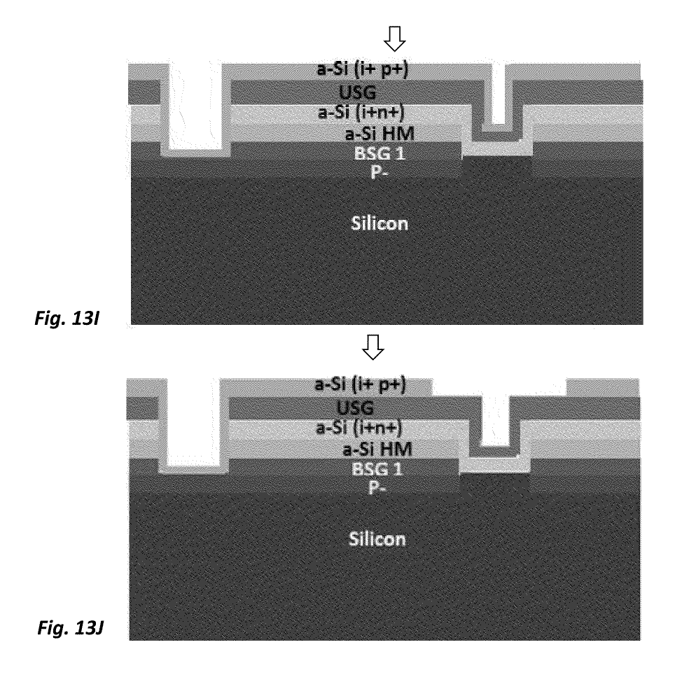

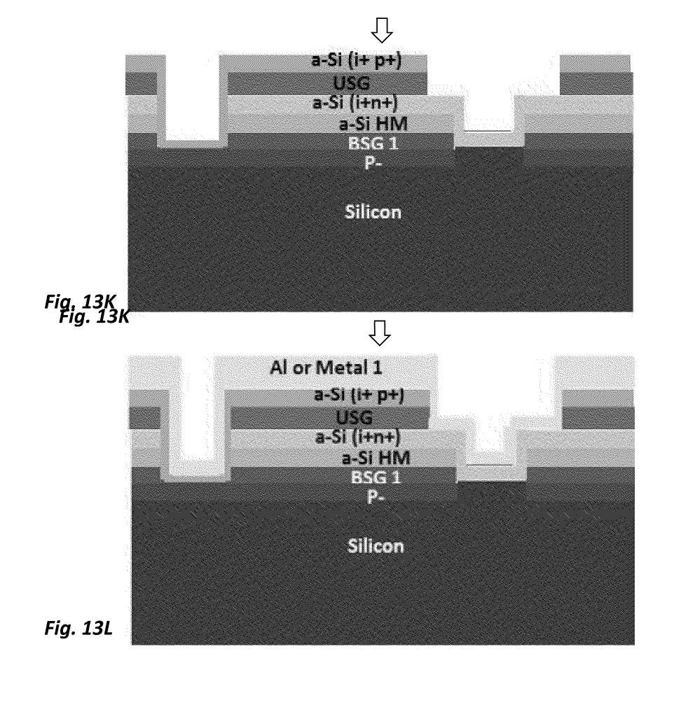

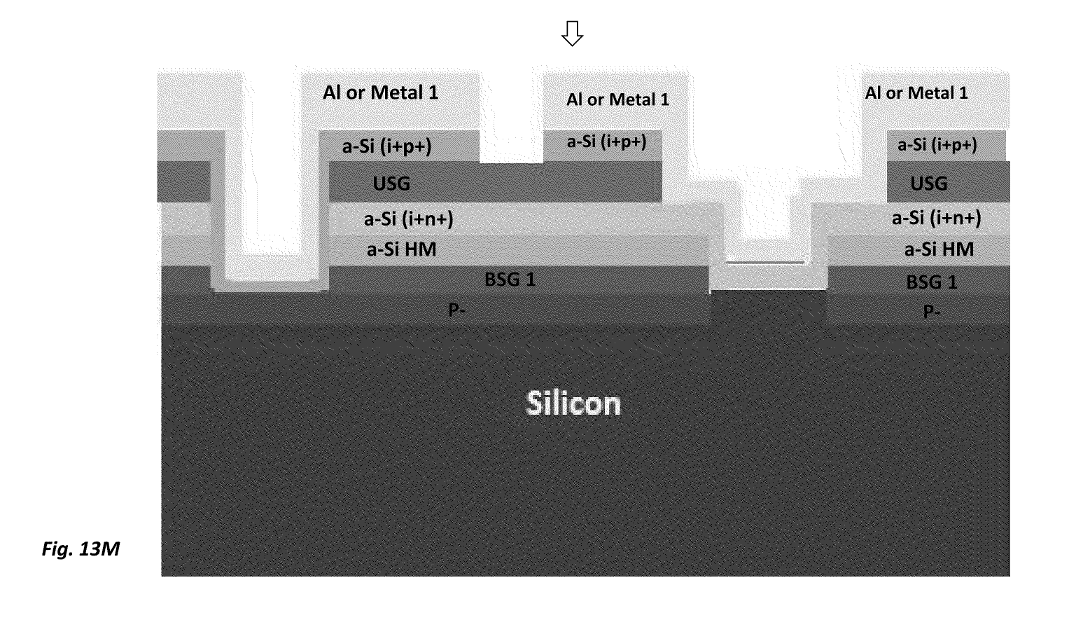

FIGS. 13A through 13M are cross-sectional diagrams showing a solar cell throughout the fabrication steps of FIG. 12B. As described with reference to and corresponding to the Steps of FIG. 12B, FIG. 13A shows a silicon wafer after the step of saw damage removal (SDR). FIG. 13B shows the structure after the step of APCVD of BSG1 and the step of PECVD of a-Si hardmask. FIG. 13C shows the structure after the step of Laser PW stopping on oxide (PW specifically referring to phosphorous window and generally describing base contact opening). FIG. 13D shows the structure after the step of HF dip to open BSG1. FIG. 13E shows the structure after the step of anneal to drive in the emitter. FIG. 13F shows the structure after the step of PECVD of intrinsic amorphous silicon (i a-Si) plus n+ amorphous silicon (a-Si) and the step of APCVD USG. FIG. 13G shows the structure after the step of Laser SE to open through hardmask (SE specifically referring to selective emitter and generally referring to selective emitter contact). FIG. 13H shows the structure after the step of Hf dip to open BSG1 in the emitter area. FIG. 13I shows the structure after the step of PECVD of i a-Si (intrinsic amorphous silicon) plus p+ a-Si. FIG. 13J shows the structure after the step of laser isolation and opening on base to remove p+ a-Si.). FIG. 13K shows the structure after the step of HF dip to remove the USG and expose n+ a-Si.). FIG. 13L shows the structure after the step of screen print paste (shown as Al or Metal 1 in FIG. 13L). FIG. 13M shows the structure after the step of post paste anneal.

The process flows outlined above should not be taken in the limiting sense. It is readily apparent from the detailed discussion above that the there are several possible ways to create more variations around these flows. Such variations, although, not explicitly stated, are implicit.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A back contact back junction photovoltaic solar cell comprising:
a semiconductor light absorbing layer having a front side and a backside;
base regions and emitter regions on said semiconductor light absorbing layer backside;
an amorphous silicon passivating layer on said base regions;
a first level base and emitter metallization, said first level metallization contacting said emitter regions and contacting said amorphous silicon passivating on said base regions;
an electrically insulating backplane on said first level metallization;
a second level metallization contacting said first level metallization through conductive vias in said electrically insulating dielectric.

2. The back contact back junction photovoltaic solar cell of claim 1, wherein said first level base and emitter metallization is aluminum.
